(19) United States
(12) Patent Application Publication
(10) Pub. No.: US 2004/0104044 A1
(43) Pub. Date: Jun. 3, 2004

(54) [PRINTED CIRCUIT BOARD DESIGN]

(76) Inventor: SUNG-MAO WU, KAOHSIUNG (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,744

(22) Filed: Aug. 14, 2003

(30) Foreign Application Priority Data
Oct. 24, 2002 (TW) 91124658

(51) Int. Cl. H05K 7/06

(52) U.S. Cl. 174/262

(57) ABSTRACT

A printed circuit board comprises a plurality of patterned circuit layers, a plurality of insulation layers and a plurality of circuits. Each insulation layer is located between a pair of neighboring patterned circuit layers for isolating the patterned circuit layers. The insulation layer and the patterned circuit layers together form a laminated layer. The circuits are formed on the sidewalls of the printed circuit board or the interior sidewalls of a cavity or an opening within the printed circuit board for interconnecting various patterned circuit layers electrically.

### CROSS REFERENCE TO RELATED APPLICATIONS

This application claims the priority benefit of Taiwan application serial no. 91124658, filed on Oct. 24, 2002.

### BACKGROUND OF INVENTION

1. Field of Invention

The present invention relates to a substrate with sidewall circuits. More particularly, the present invention relates to a substrate design with a portion of the circuit running along the sidewalls of the substrate.

2. Description of Related Art

With great advance in high-tech electronics and manufacturing in recent years, personalized and multi-functional electronic products are developed. Moreover, most electronic products are designed with the concept of miniaturization in mind. In semiconductor manufacturing, substrate type carrier is a commonly used package component. The two major types of substrates are laminated substrates and build-up substrates. The laminated substrate comprises of a stack of alternately placed patterned circuit layers and insulation layers. Since the laminated substrate is able to accommodate lots of circuits and provide good electrical connections between devices, its has become a mainstream substrate for constructing flip-chip packages.

The patterned circuit layer is, for example, a copper film whose pattern is imprinted by conducting photolithographic and etching processes. The insulation layer is positioned between each pair of neighboring patterned circuit layers to isolate the circuit layers electrically. To connect two different patterned circuit layers electrically, plated through holes (PTH) or vias are used. The insulation layer is fabricated using a material such as glass epoxy resin (FR-4, FR-5), bismaleimide-triazine (BT) or epoxy resin. In addition, the substrate can be used as a package substrate or a printed circuit board substrate. To be useful as a package substrate, a plurality of junction pads are formed on the surface to serve as contacts with a chip. On the other hand, to be useful as a printed circuit board, a plurality of junction pads are formed on the surface to serve as contacts with electrical devices.

FIG. 1 is a schematic cross-sectional view of a conventional printed circuit board. As shown in FIG. 1, a printed circuit board 100 mainly comprises a plurality of patterned circuit layers 110, 112, 118 and a plurality of insulation layers 102, 104, 106, 108 alternately stacked over each other. The insulation layer 104 is an insulating core layer made from epoxy resin or imide compound. The insulation layers 102, 106, 108 are made from epoxy resin. The patterned circuit layers 110, 112, 118 are patterned copper films formed by conducting photolithographic and etching processes in sequence. Electrical connections between the patterned circuit layers 110, 112, 118 are achieved through conductive vias 114, 120 and plated through hole 116 within the insulation layers. Furthermore, the insulation layers 102, 104, 106 and the patterned circuit layers 110, 112 are formed by lamination while the insulation layer 108 and the patterned circuit layer 118 are formed by a build-up process.

According to the aforementioned description, both the laminated or the build-up type of substrate include forming a plurality of conductive vias and plated through holes in the insulation layers and then forming the patterned circuit layers by conducting hole plating and circuit etching process. Through the sidewalls of the plated hole, various patterned circuit layers are interconnected electrically. However, in use of the conductive vias and plated through holes as a manner of connecting various patterned circuit layers, since the characterization impedance for the circuits formed on different patterned circuit layers may perform differently, it would cause the characterization impedance between the circuits to be mismatched with each other. In addition, the characterization impedance of the conductive vias and the through holes is affected by a thickness of the electric plating material, resulting in different quantities. This causes a difficulty of control. In other words, the characterization impedance of the vias and the through holes is not matched to the characterization impedance of circuit. Consequently, it does easily occur that the characterization impedance between the circuits to be mismatched with each other, and this easily causes effects of delay, interference and multiple reflection during transmitting signal due to the discontinuity of impedance.

### SUMMARY OF INVENTION

Accordingly, one object of the present invention is to provide a printed circuit board having circuits on the sidewall of the board for connecting different patterned circuit layers, wherein the characteristic impedance of the sidewall circuits and the patterned circuit layers matches each other. Hence, overall characteristic impedance is continuous.

Another object of this invention is to provide a printed circuit board having circuits on the sidewall of the board to reduce the number of plated through holes and conductive vias for interconnecting patterned circuit layers. Ultimately, area for accommodating circuits is expanded or area needed to accommodate a given circuit is reduced.

To achieve these and other advantages and in accordance with the purpose of the invention, as embodied and broadly described herein, the invention provides a first type of printed circuit board. The printed circuit board comprises of a plurality of patterned circuit layers, a plurality of insulation layers and a plurality of circuits. The insulation layer is inserted between a pair of neighboring patterned circuit layers to isolate and form a lamination with them. The circuits are formed on the sidewalls of the printed circuit board for connecting different patterned circuit layers electrically.

This invention also provides a second type of printed circuit board. The printed circuit comprises of a plurality of patterned circuit layers, a plurality of insulation layers and a plurality of circuits. The insulation layer is inserted between a pair of neighboring patterned circuit layers to isolate and form a lamination. The printed circuit board further includes a cavity on one of its surfaces. The cavity is a structure formed by removing a portion of the patterned circuit layers and a portion of the insulation layers. The circuits are formed on the interior sidewalls of cavity for interconnecting different patterned circuit layers electrically.

This invention also provides a third type of printed circuit board. The printed circuit comprises of a plurality of patterned circuit layers, a plurality of insulation layers and a plurality of circuits. The insulation layer is inserted between a pair of neighboring patterned circuit layers to isolate and form a lamination. The printed circuit board further includes an opening that passes through the printed circuit board. The opening is formed in a process of removing a portion of the patterned circuit layers and a portion of the insulation layers. The circuits are formed on the interior sidewalls of opening for interconnecting different patterned circuit layers electrically.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional printed circuit board.

FIG. 2 is a perspective view of a portion of the sidewall of a printed circuit board with circuits thereon according to a first preferred embodiment of this invention.

FIG. 3 is a perspective view of a portion of the sidewall circuit of a printed circuit board having a cavity thereon with circuits on one of the interior sidewalls of the cavity according to a second preferred embodiment of this invention.

FIG. 4 is a perspective view of a portion of the sidewall circuit of a printed circuit board having a through opening therein with circuits on one of the interior sidewalls of the opening according to a third preferred embodiment of this invention.

FIG. 5 is a perspective view of a portion of the sidewall circuit of a printed circuit board having a through opening or a cavity, the circuits formed on the different interior sidewalls of the cavity or opening, according to one preferred embodiment of this invention.

FIGS. 5A to 5D are schematic cross-sectional views showing major applications of the printed circuit board according to this invention to various types of packages.

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

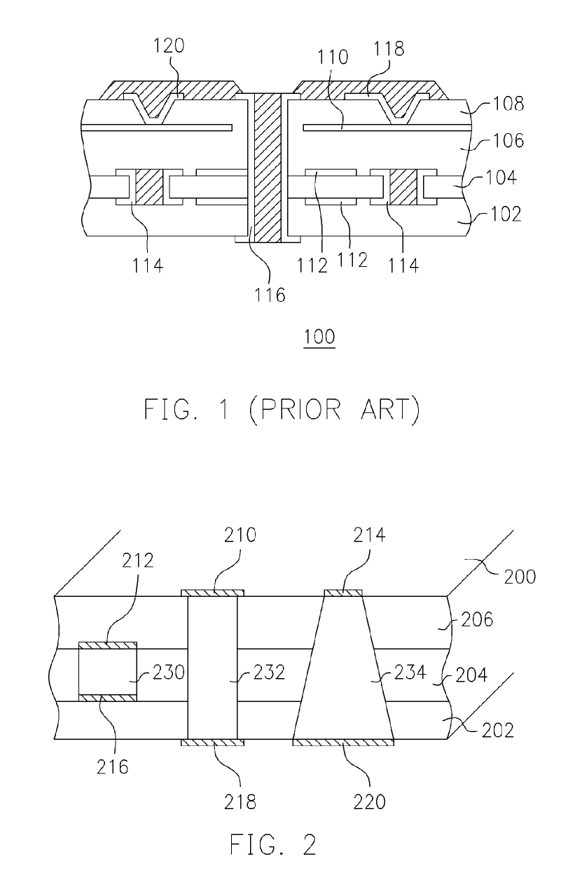

FIG. 2 is a perspective view of a portion of the sidewall of a printed circuit board with circuits thereon according to a first preferred embodiment of this invention. The printed circuit board 200 in FIG. 2 comprises of a plurality of patterned circuit layers 210, 212, 214, 216, 218, 220 and a plurality of insulation layers 202, 204, 206 alternately stacked on top of each other. The patterned circuit layers and the insulation layers are assembled to form the printed circuit board 200 either through a lamination process or a build-up process. A plurality of circuits 230, 232, 234 are formed on the sidewalls of the printed circuit board 200. The circuits are copper foils imprinted on the sidewalls through a circuit etching process for interconnecting different patterned circuit layers. Furthermore, a passivation layer is often formed over the surface of the circuits 230, 232, 234 to protect the circuits against oxidation.

In addition, since the line width of the circuit on the sidewall can be controlled by the etching process, the desired characterization impedance for a portion of the circuit between the patterned circuit layers can be respectively obtained by adjusting the line width. As a result, the impedance control can be easily achieved. In the conventional design, the conventional conductive via or through hole have a fixed size of apertures. When they are connected to the circuits with different line width, an impedance mismatch between the circuits would easily occur. In the invention, the lie width of the interconnection circuit on the sidewall can properly adjusted with respect to the actual condition, so that the conventional issue of impedance mismatch can be solved. For example, the circuit at one end coupling to the patterned circuit layer with higher characterization impedance can have a narrower line width for matching. At the same time, the circuit at one end coupling to the patterned circuit layer with lower characterization impedance can have a wider line width for matching. As a result, it can be achieved to cause the characterization impedance between the circuits to be matched with each other.

Three different embodiments of this invention are shown on the sidewall of the printed circuit board in FIG. 2. In the first embodiment, two patterned circuit layers 212 and 216 embedded within the printed circuit board 200 having an identical circuit line width are electrically connected through a circuit 230 with the same line width. Thus, the circuit connection 230 can replace the conventional conductive via. In the second embodiment, at least two patterned circuit layers 210 and 218 are formed on the surface or the interior of the printed circuit board 200 having an identical circuit line width are electrically connected through a circuit 232 with the same line width. Thus the circuit connection 232 replaces the functions of conventional through hole. In the third embodiment, at least two patterned circuit layers 214 and 220 on the surface or the interior of the printed circuit board 200 having different circuit line widths are electrically connected through a circuit line 234 whose line width varies continuous in a form of trapezoid. Thus, one end of the circuit 234 close to the patterned circuit layer 220 has a line width greater than the other end of the circuit 234 close to the patterned circuit layer 214. Basically, the line width of circuit line 234 can vary according to the actual requirement in considering the match of impedance between any concerning two patterned circuit layers.

Accordingly, various patterned circuit layers can be electrically interconnected through sidewall circuits on the printed circuit board. Moreover, the sidewall circuits may be fabricated into various geometric shapes to cater for any difference in characteristic impedance between patterned circuit layers. In other words, characteristic impedance mismatch between different patterned circuit layers when connected through a conductive via or a plated through hole is largely prevented using sidewall circuits. Furthermore, using sidewall circuits also reduces the number of conductive vias or plated through holes within the printed circuit board so that area for accommodating useful circuits is increased.

FIG. 3 is a perspective view of a portion of sidewall circuit of a printed circuit board having a cavity thereon with circuits on one of the interior sidewalls of the cavity according to a second preferred embodiment of this invention. As shown in FIG. 3, there is a cavity 302 on the surface of the printed circuit board 300. The cavity 302 is a structure formed by removing a portion of the patterned circuit layers and a portion of the insulation layers. In addition, the printed circuit board 300 further includes a plurality of circuits 320 attached to the sidewall 304 of the cavity 302 for interconnecting different patterned circuit layers electrically. Similarly, the circuits 320 are copper foils fabricated by conducting an etching process. Furthermore, width of each circuit 320 may be uniformly varied to achieve continuous characteristic impedance with the connected patterned circuit layers and to easily control the impedance between the circuits of the patterned circuit layers.

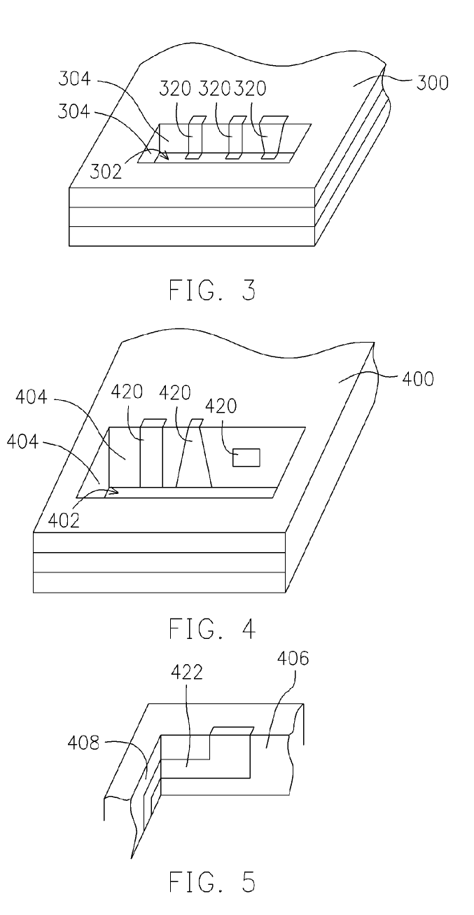

FIG. 4 is a perspective view of a portion of sidewall circuit of a printed circuit board having an opening therein with circuits on one of the interior sidewalls of the opening according to a third preferred embodiment of this invention. As shown in FIG. 4, there is an opening 402 that passes through the printed circuit board 400. The opening 402 is formed in the printed circuit board 400 by removing a portion of the patterned circuit layers and a portion of the insulation layers. In addition, the printed circuit board 400 further includes a plurality of circuits 420 attached to the sidewall 404 of the opening 402 for interconnecting different patterned circuit layers electrically. Similarly, the circuits 420 are copper foils fabricated by conducting an etching process. Furthermore, width of each circuit line 420 may be uniformly varied to achieve continuous characteristic impedance with the connected patterned circuit layers and to easily control the impedance between the circuits of the connected patterned circuit layers.

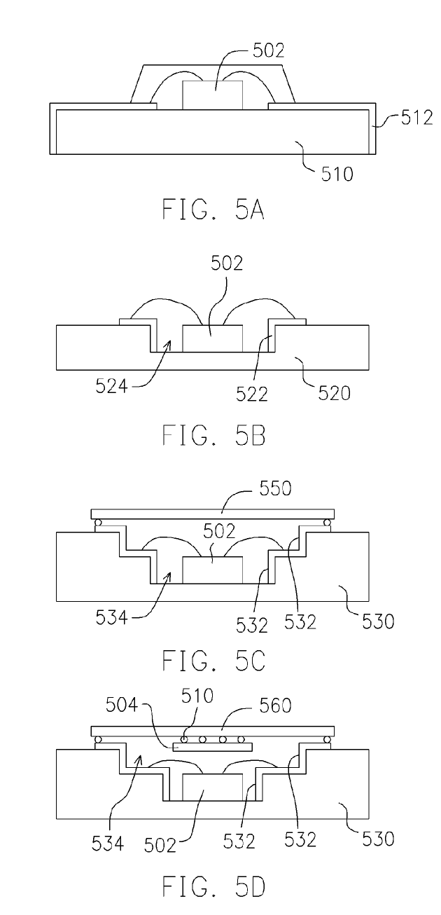

FIG. 5 is a perspective view of a portion of sidewall circuit of a printed circuit board having a through opening or a cavity, the circuits formed on the different interior sidewalls of the cavity or opening, according to one preferred embodiment of this invention. It should be noted that circuit 422 is attached to the sidewalls 406, 408 of the cavity or opening in the printed circuit board. The circuit 422 is capable of interconnecting patterned circuit layers on different sidewalls 406, 408 electrically. Similarly, width of the circuit line 422 may be uniformly varied to achieve continuous characteristic impedance with the connected patterned circuit layers and to easily control the impedance between the circuits of the connected patterned circuit layers.

FIGS. 5A to 5D are schematic cross-sectional views showing major applications of the printed circuit board according to this invention to various types of packages. In FIG. 5A, a printed circuit board 510 having a sidewall circuit 512 is provided. A chip 502 is attached to the surface of the printed circuit board 510 and electrically connected to a patterned circuit layer on the surface of the printed circuit board 510. The sidewall circuit 512 interconnects the surface patterned circuit layer to another patterned circuit layer electrically. In FIG. 5B, a cavity 524 is formed on the surface of a printed circuit board 520. A chip 502 is attached to the bottom surface of the cavity 524 and electrically connected to a patterned circuit layer. A sidewall circuit 522 interconnects the chip connected patterned circuit layer with a different patterned circuit layer electrically. In FIGS. 5C and 5D, a patterned circuit layer on the surface of a printed circuit board 530 is electrically connected to a substrate 550 or 560. The substrate 550 is a printed circuit board while the substrate 560 is a packaging substrate, for example. The substrate 560 has a plurality of junction pads 510 for connecting with the chip 504. In addition, the surface of the printed circuit board 530 includes a cavity 534 with a step sidewall profile. Circuits 532 are attached to the interior sidewalls of the cavity 534. A chip 502 is attached to the bottom surface of the cavity 534 and electrically connected to a patterned circuit layer. The sidewall circuit 532 interconnects the chip connected patterned circuit layer with a different patterned circuit layer electrically.

In conclusion, major advantages of the printed circuit board according to this invention includes: 1. Circuits are formed on the sidewalls of a printed circuit board or on the interior sidewalls of a cavity or opening within the printed circuit for interconnecting different patterned circuit layers. Hence, the circuit on the sidewall can interconnect the patterned circuit layers, and the line width can be properly adjusted to achieve the features of continuous impedance between the patterned circuit layers and to easily control the impedance between the circuits of the patterned circuit layers. 2. Using sidewall circuit lines with varying line width instead of conductive vias or plated through holes to connect various patterned circuit layers, characteristic impedance mismatch due to such interconnections is reduced. 3. Since some of the patterned circuit layers are interconnected through sidewall circuits, the total number of conductive vias or plated through holes within a printed circuit board can be reduced. Hence, more area is available for forming layout circuits.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A printed circuit board, at least comprising:
a plurality of patterned circuit layers;
an insulation layer between the patterned circuit layers for isolating the patterned circuit layers from each other, wherein the insulation layer and the patterned circuit layers together form a laminated layer; and
at least one side circuit on a sidewall of the laminated layer for electrically interconnecting at least any two of the patterned circuit layers.

2. The printed circuit board of claim 1, wherein the at least one side circuit has a shape structure so that impedances of the sidewall circuits and the patterned circuit layers are matched with each other.

3. The printed circuit board of claim 1, wherein the at least one side circuit includes a uniform width.

4. The printed circuit board of claim 1, wherein the at least one side circuit includes a varying width.

5. The printed circuit board of claim 1 wherein the at least one side circuit includes a trapezoidal shape.

6. The printed circuit board of claim 1, wherein the least one side circuit includes a bending circuit on the sidewall.

7. A printed circuit board, at least comprising:
a plurality of patterned circuit layers;
an insulation layer between the patterned circuit layers for isolating the patterned circuit layers from each other, wherein the insulation layer and the patterned circuit layers together form a laminated layer, wherein the laminated layer includes a cavity; and
at least one side circuit implemented on an interior sidewall of the cavity for electrically interconnecting at least any two of the patterned circuit layers.

8. The printed circuit board of claim 7, wherein the at least one side circuit has a shape structure so that impedances of the sidewall circuits and the patterned circuit layers are matched with each other.

9. The printed circuit board of claim 7, wherein the at least one side circuit includes a uniform width.

10. The printed circuit board of claim 7, wherein the at least one side circuit includes a varying width.

11. The printed circuit board of claim 7, wherein the at least one side circuit includes a trapezoidal shape.

12. The printed circuit board of claim 7, wherein the least one side circuit includes a bending circuit on the sidewall.

13. A printed circuit board, at least comprising:
a plurality of patterned circuit layers;
an insulation layer between the patterned circuit layers for isolating the patterned circuit layers from each other, wherein the insulation layer and the patterned circuit layers together form a laminated layer, wherein the laminated layer includes an opening; and
at least one side circuit implemented on an interior sidewall of the opening for electrically interconnecting at least any two of the patterned circuit layers.

14. The printed circuit board of claim 13, wherein the opening comprises a through hole in the laminated layer.

15. The printed circuit board of claim 13, wherein the at least one side circuit has a shape structure so that impedances of the sidewall circuits and the patterned circuit layers are matched each other.

16. The printed circuit board of claim 13, wherein the at least one side circuit include a uniform width.

17. The printed circuit board of claim 13, wherein the at least one side circuit includes a varying width.

18. The printed circuit board of claim 13, wherein the at least one side circuit includes a trapezoidal shape.

19. The printed circuit board of claim 13, wherein the least one side circuit includes a bending circuit on the sidewall.

20. A printed circuit board, at least comprising:
a plurality of patterned circuit layers;
an insulation layer between the patterned circuit layers for isolating the patterned circuit layers from each other, wherein the insulation layer and the patterned circuit layers together form a laminated layer, wherein the laminated layer has a sidewall including at least two selected from the group consisting of an edge sidewall of the laminated layer, an interior sidewall of a cavity of the laminated layer, and an interior sidewall of an opening of the laminated layer; and
at least one side circuit implemented on the sidewall electrically interconnecting at least two of the patterned circuit layers.
